(19) United States
(12) Patent Application Publication
(10) Pub. No.: US 2015/0380284 A1
(43) Pub. Date: Dec. 31, 2015

(54) APPARATUS FOR PROCESSING SUBSTRATE

(71) Applicant: EUGENE TECHNOLOGY CO., LTD., Gyeonggi-do (KR)

(72) Inventors: Il-Kwang YANG, Gyeonggi-do (KR); Byoung-Gyu SONG, Gyeonggi-do (KR); Kyong-Hun KIM, Gyeonggi-do (KR); Yong-Ki KIM, Chungcheongnam-do (KR); Yang-Sik SHIN, Gyeonggi-do (KR)

(73) Assignee: EUGENE TECHNOLOGY CO., LTD., Gyeonggi-do (KR)

(21) Appl. No.: 14/766,150

(22) PCT Filed: Feb. 17, 2014
(86) PCT No.: PCT/KR2014/001257

§ 371 Date: Aug. 6, 2015

(30) Foreign Application Priority Data
Mar. 27, 2013 (KR) 10-2013-0032529

(51) Int. Cl. H01L 21/67

(52) U.S. Cl. CPC H01L 21/67098

(57) ABSTRACT

Provided is a substrate processing apparatus. The substrate processing apparatus includes a process chamber having an inner space in which a substrate transferred from the outside is accommodated, and a process with respect to the substrate is performed, hot-wire heaters disposed in a sidewall of the process chamber, the hot-wire heaters being disposed around the inner space to heat the substrate, and a cooling tube in which a refrigerant supplied from the outside flows, the cooling tube being disposed between the hot-wire heaters along the sidewall of the process chamber.

### TECHNICAL FIELD

The present invention disclosed herein relates to an apparatus for processing a substrate, and more particularly, to a substrate processing apparatus in which a heater installed within a process chamber for performing processes with respect to a substrate and an internal temperature of the process chamber are easily cooled.

### BACKGROUND ART

Substrate processing apparatuses used for manufacturing semiconductors, flat panel displays, photovoltaic cells, and the like may be apparatuses that perform an essential thermal processing process for crystallizing and phase-changing a predetermined thin film that is deposited on a substrate such as a silicon wafer or a glass substrate.

Typically, in case of manufacturing liquid crystal displays or thin-film crystalline silicon photovoltaic cells, there is a silicon crystallization apparatus for crystallizing amorphous silicon deposited on the a glass substrate into poly silicon. To perform the crystallization process, the substrate on which the predetermined thin film is formed has to be heated. For example, it is necessary that a process temperature for crystallizing the amorphous silicon is about 550° C. to about 600° C.

Such a substrate processing apparatus may be classified into a single wafer type substrate processing apparatus in which a substrate processing process is performed on one substrate and a batch type substrate processing apparatus in which a substrate processing process is performed on a plurality of substrates. The single wafer type substrate processing apparatus has an advantage in that its structure is simple. However, the single wafer type substrate process apparatus may be deteriorated in productivity. Thus, the batch type substrate processing apparatus may be in the spotlight.

### DISCLOSURE

### Technical Problem

The present invention provides a substrate processing apparatus in which a heater for heating a substrate and an internal temperature of a process chamber are easily cooled.

Further another object of the present invention will become evident with reference to following detailed descriptions and accompanying drawings.

### Technical Solution

Embodiments of the present invention provide substrate processing apparatuses including: a process chamber having an inner space in which a substrate transferred from the outside is accommodated, and a process with respect to the substrate is performed; hot-wire heaters disposed in a sidewall of the process chamber, the hot-wire heaters being disposed around the inner space to heat the substrate; and a cooling tube in which a refrigerant supplied from the outside flows, the cooling tube being disposed between the hot-wire heaters along the sidewall of the process chamber.

In some embodiments, the process chamber may include an inlet port disposed on one side of the process chamber, and the cooling tube is taken into the inlet port, and the substrate processing apparatus may further include a supply line connected to the cooling tube disposed on the inlet port to supply the refrigerant.

In other embodiments, the substrate processing apparatuses may further include an internal reaction tube disposed in the inner space to partition the inner space into the inside and the outside, the internal reaction tube having a process space in which the process with respect to the substrate is performed, and the cooling tube has a plurality of injection holes for injecting the refrigerant toward the outside of the internal reaction tube.

In still other embodiments, the substrate processing apparatuses may further include an exhaust port communicating with an exhaust hole defined in an upper portion of the process chamber to exhaust the refrigerant injected through the injection holes to the outside.

In even other embodiments, the injection holes may be disposed inclined upward.

### Advantageous effects

According to the embodiments of the present invention, the temperature of the process chamber, which increases to the predetermined temperature, may be easily cooled.

### DESCRIPTION OF DRAWINGS

FIG. 1 is a schematic view of a substrate processing apparatus according to an embodiment of the present invention;

FIG. 2 is a view of a state in which a substrate holder is switched into a process position in FIG. 1;

FIG. 3 is an enlarged view of a process chamber of FIG. 1;

FIG. 4 is a view illustrating an arrangement of an injection hole of FIG. 3; and

FIG. 5 is a view of a substrate processing apparatus according to another embodiment of the present invention.

### BEST MODE

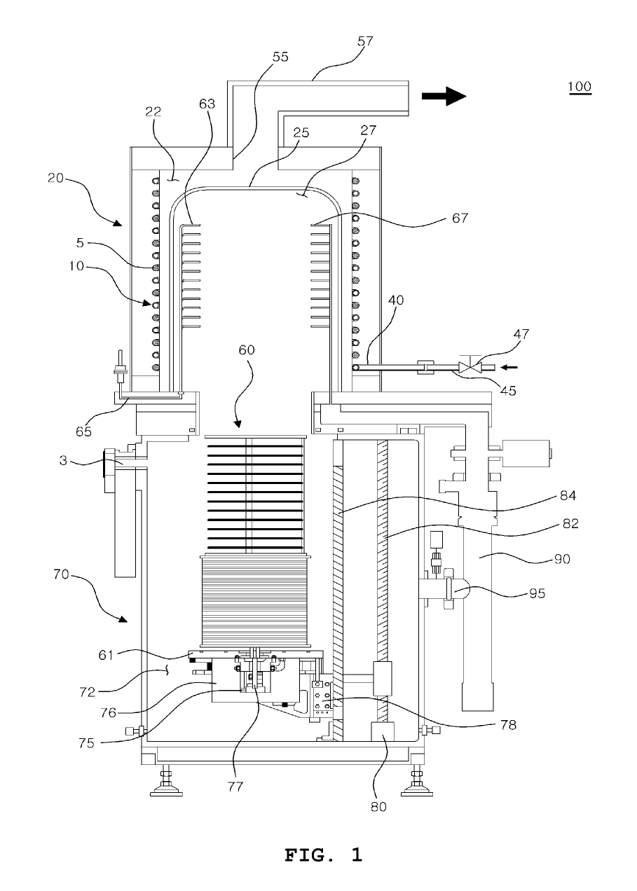

Hereinafter, exemplary embodiments of the present invention will be described in detail with reference to FIGS. 1 to 4. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the thicknesses of layers and regions are exaggerated for clarity. It is obvious to a person skilled in the art that the embodiments of the present invention are applicable to various objects to be processed in addition to the substrate W that is described in the current embodiments.

Typically, a substrate processing apparatus may be classified into a single wafer type substrate processing apparatus in which a substrate processing process is performed on one substrate and a batch type substrate processing apparatus in which a substrate processing process is performed on a plurality of substrates. The single wafer type substrate processing apparatus has an advantage in that its structure is simple. However, the single wafer type substrate process apparatus may be deteriorated in productivity. Thus, the batch type substrate processing apparatus may be in the spotlight.

Also, to perform the crystallization process, the substrate processing apparatus includes a heater for heating a substrate on which a predetermined thin film is formed. For example, a process temperature for crystallizing amorphous silicon, i.e., an internal temperature of a chamber may be about 550° C. to about 600° C. Here, the process temperatures required for processes may be different from each other. Also, a semiconductor device may be manufactured by repeatedly performing deposition, photographing (pattern formation), etching, and cleaning processes on a substrate, e.g., a silicon wafer.

To perform the above-described processes, the inside of a chamber of the substrate processing apparatus may heated to a high temperature, and then, be naturally cooled by turning the heater installed within the chamber off, thereby preparing the next process. That is, it takes a long time to cool the inside of the chamber up to a temperature for required for the next process. As a result, in the performing of the processes with the substrate, an available rate may be reduced to deteriorate productivity. Thus, a substrate processing apparatus in which an internal temperature of a process chamber is capable of being easily cooled will be described below.

The present invention is not limited to a kind of substrate to be processed. Thus, substrates formed of various materials such as glass, plastic, polymer, silicon wafer, stainless steel, sapphire materials and the like, which are generally used in the overall semiconductor manufacturing process. Also, the processing of the substrate may be understood as processing of a predetermined or pattern formed on the substrate as well as processing of the substrate itself.

Also, the present invention is not limited to use of the substrate processing apparatus. Thus, the overall semiconductor processes, for example, a deposition process, an etching process, a surface processing process, and the like may be performed by using the substrate processing apparatus according to the present invention. In addition, only main components of the present invention will be described below. Also, it is obvious that various components may be additionally provided to the substrate processing apparatus of the present invention according to purpose of utilization.

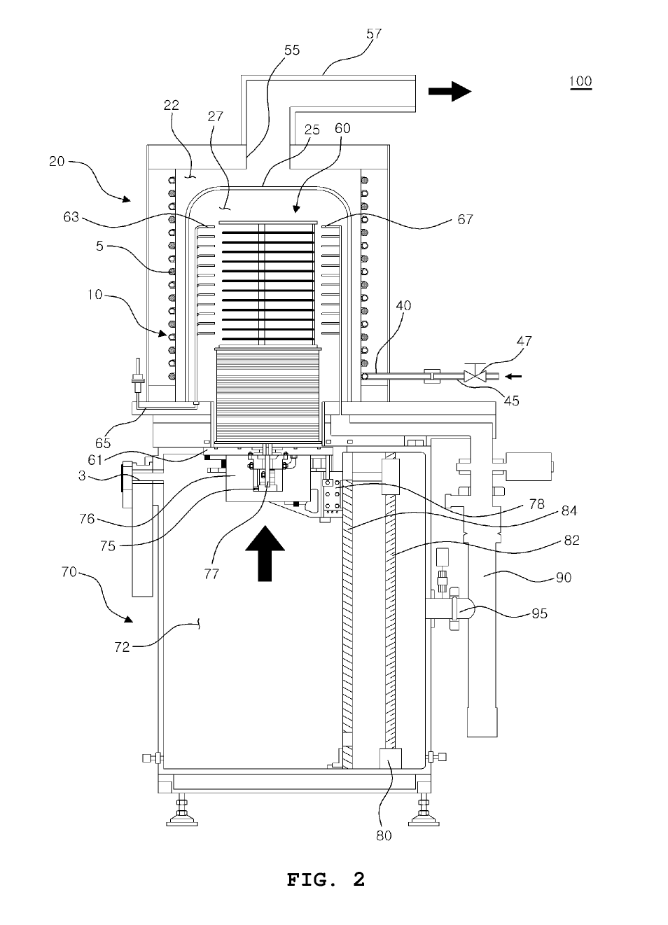

FIG. 1 is a schematic view of a substrate processing apparatus according to an embodiment of the present invention. FIG. 2 is a view of a state in which a substrate holder is switched into a process position in FIG. 1. Referring to FIGS. 1 and 2, a substrate processing apparatus 100 may include a lower chamber 70 having an opened upper portion. The lower chamber 70 has a passage through which a substrate passes. The substrate may be loaded into the lower chamber 70 through the passage. A gate valve (not shown) may be disposed outside the passage, and the passage may be opened or closed by the gate valve.

The substrate processing apparatus 100 includes a substrate holder (also, referred to as a “boat”) 60 on which a plurality of substrates are stacked. Here, the substrates are vertically stacked on the substrate holder 60. As illustrated in FIG. 1, while the substrate holder 60 is disposed in a stacking space 72 provided within the lower chamber, the substrates may be stacked within the substrate holder 60. The substrate holder 60 is connected to a rotation shaft 77, and the rotation shaft passes through the lower chamber 70 and is connected to an elevation motor 80 and a rotation motor 75. The rotation motor 75 may be disposed on a motor housing 76. The rotation motor 75 may operate, while the process with respect to the substrate is performed, to rotate the substrate holder 60 together with the rotation shaft 77.

The motor housing 76 is fixed to a bracket 78, and the bracket 78 is connected to a lower guide 84 that is connected to a lower portion of the lower chamber 70 and thus is elevated along an elevation rod 82. The bracket 78 is screw-coupled to the elevation rod 82, and the elevation rod 82 is rotated by the elevation motor 80. That is, the elevation rod 82 may be rotated by the rotation of the elevation motor 80. Thus, the bracket 78 and the motor housing 76 may be elevated together with each other.

Thus, the rotation shaft 77 and the substrate holder 60 may be elevated together with each other, and the substrate holder 60 may be switched into the stacking position and a process position by the elevation motor 80. A bellows (not shown) may be disposed between the lower chamber 70 and the motor housing 76 to maintain sealing of the inside of the lower chamber 70.

A process chamber 20 has an inner space 22 in which the process with respect to the substrate is performed. An internal reaction tube 25 is disposed in the inner space 22.

The internal reaction tube 25 provides a process space 27 in which the process with respect to the substrate is performed. The internal reaction tube 25 partitions the inside of the process chamber 20 into the inner space 22 and the process space 27. As illustrated in FIG. 2, when the substrate holder 60 in which the plurality of substrates are accommodated may ascend into the process space 27 and be switched to the process position, a space between the substrate and a process gas may be minimized to perform the process.

The substrate processing apparatus 100 may include a plurality of supply nozzles 63 for supplying a reaction gas into the process space 27 and exhaust nozzles 67. Supply holes (not shown) of the supply nozzles 63 may be defined at heights different from each other. The supply nozzles 63 and the supply hole may be disposed in the process space 27 to supply a reaction gas onto the stacked substrates. Also, each of the exhaust nozzles 67 may be disposed at a side opposite to each of the supply nozzles 63 to discharge non-reaction gas and reaction byproducts to the outside which are generated during the processes.

The exhaust nozzles 67 are connected to a first output line 90. The non-reaction gas and reaction byproducts which are suctioned through the exhaust nozzles 67 are discharged through a first output line 90. An output valve (not shown) may be disposed in the first output line 90 to open or close the first output line 90. Also, a turbopump (not shown) may be disposed on the first output line 90 to forcibly discharge the non-reaction gas and reaction byproducts. The lower chamber 70 may also include a second output line 95, and the stacking space 72 may be exhausted the second output line 95. Also, the second output line 95 may communicate with the first output line 90.

Also, a base 61 may be may be disposed under the substrate holder 60 and elevated together with the substrate holder 60 as the rotation shaft 77 is elevated. The base 61 may close an opened lower portion of the internal reaction tube 25 to prevent heat within the internal reaction tube 25 from being transferred into the stacking space 72 within the lower chamber 20.

That is, when the substrate holder 60 ascends, and the substrates are stacked on a slot of the substrate holder 60, the substrate holder 60 may ascend by a predetermined distance so that the substrates are successively stacked on the next slot of the substrate holder 60. When the substrates are stacked on the substrate holder 60, the substrate holder 60 may ascend into the process chamber 20 and be disposed in the process space 27 to perform the process with respect to the substrate.

That is, the process chamber 20 has the inner space 22, in which the substrate transferred from the lower chamber 70 is accommodated, to perform the process with respect to the substrate within the internal reaction tube 25 that partitions the inside of the process chamber into the inner space 22 and the process space 27. A hot-wire heater 5 may be disposed around the inner space 22 in a sidewall of the process chamber 20. An inlet port 30 may be disposed on one side of the process chamber 20, and thus, a cooling tube 10 may be inserted into the inlet port 30. Also, a supply line 35 may be connected to the cooling tube 10 disposed on the inlet port 30 to supply the refrigerant into the cooling tube 10 through the supply line 35. Thus, the supply line 35 may be connected to a passage (see reference numeral 15 of FIG. 4) of the cooling tube 10 disposed on the inlet port 30 to supply the refrigerant into the passage.

The cooling tube 10 may be spaced a predetermined distance from the hot-wire heater 5 and spirally disposed along the sidewall of the process chamber 20. The cooling tube 10 may include a tube body (see reference numeral 13 of FIG. 4) having a predetermined thickness and a passage (see reference numeral 15 of FIG. 4) defined within the tube body. The cooling tube 10 may have a polygonal section including a circular section. The cooling tube 10 may be formed of a material having superior heat resistance. Also, an outlet port (not shown) may be disposed on the other side of the process chamber 20, and thus, the cooling tube 10 inserted through the inlet port 30 may be withdrawn through the outlet port.

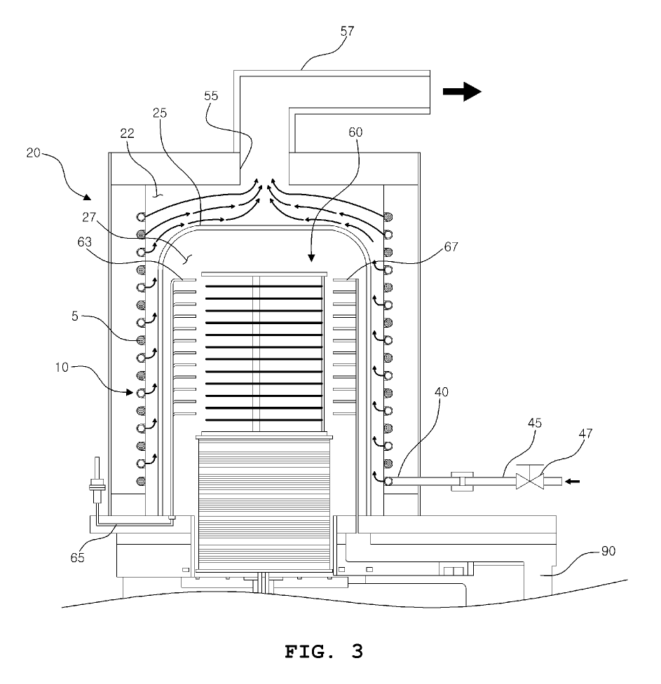

Also, a discharge line (not shown) may be connected to the cooling tube 10 disposed on the outlet port to discharge the refrigerant that is heated while passing through the inside of the process chamber 20. A pump (not shown) for easily discharging the refrigerant may be connected to the discharge line, and a valve 47 may be disposed in the supply line 35 or the discharge line to adjust a flow and flow rate of the refrigerant. A configuration and operation process of the cooling tube 10 will be described with reference to FIGS. 3 and 4.

FIG. 3 is an enlarged view of a process chamber of FIG. 1, and FIG. 4 is a view illustrating a modified example of the cooling tube of FIG. 3. As illustrated in FIGS. 3 and 4, a plurality of injection holes 17 are defined in a tube body 13, and a refrigerant supplied through the passage 15 may be injected toward the internal reaction tube 25. As described above, the supply line 35 is connected to the cooling tube 10 disposed on the inlet port 30 to supply the refrigerant through the supply line 35. Thus, the supply line 35 is connected to the passage 15 of the cooling tube 10 disposed on the inlet port 30 to supply the refrigerant into the passage 15.

Thus, the refrigerant may be injected toward the outside of the internal reaction tube 25 through the plurality of injection holes 17 defined in the cooling tube 10. The refrigerant may be a refrigerant gas including nitrogen. The hot-wire heater 5 and the inner space of the process chamber 20 may be reduced through the refrigerant injected through the injection holes 17. Also, an exhaust hole 55 may be defined in an upper portion of the process chamber 20. An exhaust port 57 may communicate with the exhaust hole 55 to discharge the refrigerant injected through the injection holes 17 to the outside.

As illustrated in FIGS. 4A and 4B, each of the injection holes 17 may be tilted toward the outside of the internal reaction tube 25, and thus, the refrigerant may flow upward. When the refrigerant is a cooling gas, the inlet port 40 is disposed under an outlet 30 to supply the cooling gas through the inlet port 40 and form an air flow so that the heated cooling gas smoothly flows toward the exhaust hole 55, thereby discharging the cooling gas to the outside. As illustrated in FIG. 4C, the injection holes 17 may be vertically provided in plurality. Since the injection holes 17 are formed in predetermined positions to inject the refrigerant toward the internal reaction tube 25, the hot-wire heater 5 and an internal temperature of the process chamber 20 may be effectively cooled.

That is, temperatures that are set when processes are performed within the substrate processing apparatus 100 may be different from each other. For example, when the inside of the process chamber 20 is heated at a predetermined temperature by using the hot-wire heater 5 to increases in temperature within the process chamber 20, and then, to reduce the internal temperature of the process chamber 20 so as to perform the next process, the current applied into the hot-wire heater 5 may be blocked, and also, the refrigerant may be injected through the injection holes 17 of the cooling tube 10 to quickly cool the hot-wire heater 10 and the internal temperature of the process chamber 20. Thus, the process time may be effectively reduced to increase process efficiency with respect to the substrate, thereby improving productivity.

Although the present invention is described in detail with reference to the exemplary embodiments, the invention may be embodied in many different forms. Thus, technical idea and scope of claims set forth below are not limited to the preferred embodiments.

### MODE FOR INVENTION

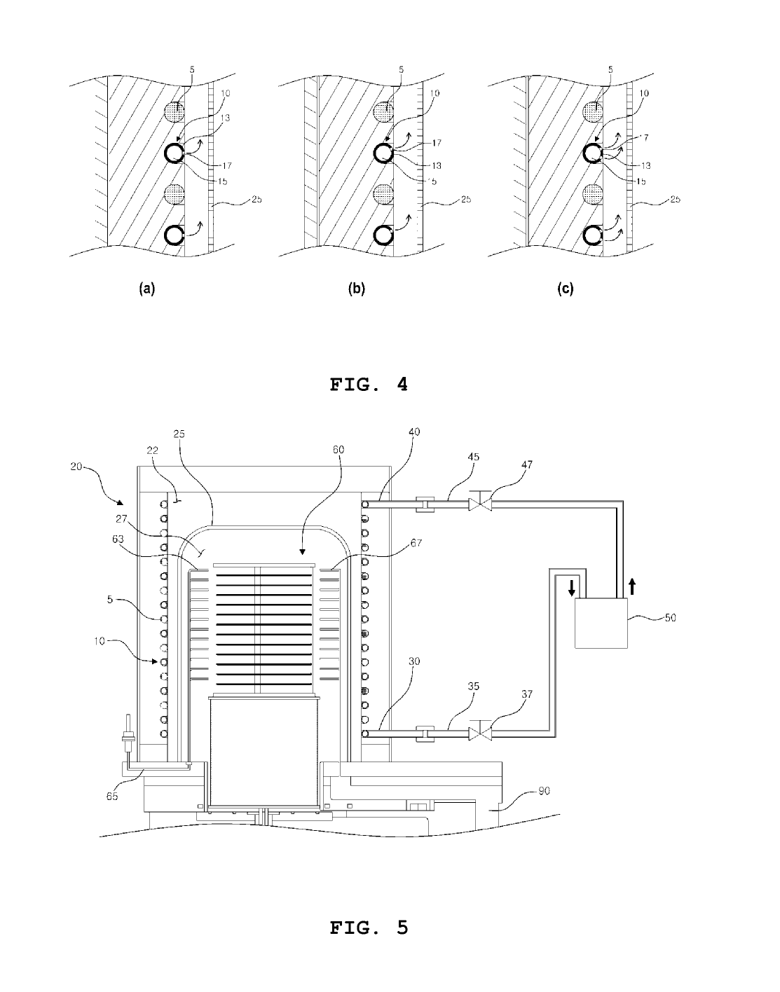

Hereinafter, exemplary embodiments of the present invention will be described in detail with reference to FIG. 5. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the thicknesses of layers and regions are exaggerated for clarity. It is obvious to a person skilled in the art that the embodiments of the present invention are applicable to various objects to be processed in addition to the substrate W that is described in the current embodiments.

FIG. 5 is a view of a substrate processing apparatus according to another embodiment of the present invention. For convenience of description, omitted components and operation processes may be substitute with the explanation of the substrate processing apparatus described with reference to FIGS. 1 to 4, and thus, differences therebetween will be mainly described below. Referring to FIG. 5, an inlet port 40 and an outlet port 30 are disposed on one side and the other side of a process chamber 20, respectively. A cooling tube 10 may be taken in and out through the inlet port 40 and the outlet port 30.

A supply line 45 may be connected to a cooling tube 10 disposed on the inlet port 40 to supply a refrigerant into the cooling tube 10 through the supply line 45. A discharge line 35 may be connected to the cooling tube 10 disposed on the outlet port 30. If the refrigerant is coolant, the inlet port 40 may be disposed above the outlet port 30. The coolant may be supplied into the inlet port disposed on the upper portion of the process chamber 20 and be discharged through the outlet port 30 disposed on the lower portion of the process chamber 20 to allow the coolant to smoothly flow by using its weight.

Also, the supply line 45 is connected to a passage (see reference numeral 15 of FIG. 4) of the cooling tube 10 disposed on the inlet port 40 to supply the refrigerant into the passage. Also, the discharge line 35 may be connected to the cooling passage 10 disposed on the inlet port 30 to discharge the refrigerant that is heated while passing through the process chamber 20. If the substrate processing apparatus 100 does not have an exhaust hole (see reference numeral 55 of FIG. 1) defined in the process chamber 20 and injection holes (see reference numeral 17 of FIG. 4) of the cooling tube, the refrigerant supplied through the supply line 45 may be entirely discharged through the discharge line 35. If the refrigerant is a cooling gas, the inlet port 40 may be disposed under the outlet port 30 to smoothly discharge the cooling gas by using a specific gravity difference due to the heating of the cooling gas.

In addition, when the refrigerant is coolant, the supply line 45 and the discharge line 35 may be connected to a chiller 50. The refrigerant heated while passing through the inside of the process chamber 20 may flow into the chiller 50 through the discharge line 35. Then, the coolant cooled by the chiller 50 may be circulated through the supply line 45. On the other hand, when the refrigerant is a cooling gas, the refrigerant heated in a state where the chiller 50 is removed may be discharged to air through the discharge line 35.

Thus, when different processes are performed in the substrate processing apparatus, the processes may be performed at differently set temperatures. That is, when the inside of the process chamber 20 is heated at a predetermined temperature by using the hot-wire heater 5 to increases in temperature within the process chamber 20, and then, to reduce the internal temperature of the process chamber 20 so as to perform the next process, the current applied into the hot-wire heater 5 may be blocked, and also, the refrigerant may be injected into the cooling tube 10 to quickly cool the internal temperature of the process chamber 20 and reduce a process time, thereby improving efficiency and productivity with respect to the substrate.

Although the present invention is described in detail with reference to the exemplary embodiments, the invention may be embodied in many different forms. Thus, technical idea and scope of claims set forth below are not limited to the preferred embodiments.

### INDUSTRIAL APPLICABILITY

The present invention may be applicable to a various apparatus for manufacturing semiconductor or a various method for manufacturing semiconductor.

1. A substrate processing apparatus comprising:
a process chamber having an inner space in which a substrate is accommodated, and a process with respect to the substrate is performed;
hot-wire heaters disposed in a sidewall of the process chamber, the hot-wire heaters being disposed around the inner space to heat the substrate; and
a cooling tube in which a refrigerant supplied from the outside flows, the cooling tube being disposed between the hot-wire heaters along the sidewall of the process chamber.

2. The substrate processing apparatus of claim 1, wherein the process chamber comprises an inlet port disposed on one side of the process chamber, and the cooling tube is taken into the inlet port, and
the substrate processing apparatus further comprises a supply line connected to the cooling tube disposed on the inlet port to supply the refrigerant.

3. The substrate processing apparatus of claim 2, further comprising an internal reaction tube disposed in the inner space to partition the inner space into the inside and the outside, the internal reaction tube having a process space in which the process with respect to the substrate is performed, and
the cooling tube has a plurality of injection holes for injecting the refrigerant toward the outside of the internal reaction tube.

4. The substrate processing apparatus of claim 3, further comprising an exhaust port communicating with an exhaust hole defined in an upper portion of the process chamber to exhaust the refrigerant injected through the injection holes to the outside.

5. The substrate processing apparatus of claim 3, wherein the injection holes are disposed inclined upward.

6. The substrate processing apparatus of claim 4, wherein the injection holes are disposed inclined upward.
